(19) United States
(12) Patent Application Publication
(10) Pub. No.: US 2008/0252837 A1
(43) Pub. Date: Oct. 16, 2008

(54) LIQUID CRYSTAL DISPLAY DEVICE AND MANUFACTURING METHOD THEREOF

(75) Inventor: Atsushi YAMAZAKI, Hakusan-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Toshiba Matsushita Display Technology Co., Ltd., Tokyo (JP)

(21) Appl. No.: 12/051,955

(22) Filed: Mar. 20, 2008

(30) Foreign Application Priority Data
Mar. 22, 2007 (JP) 2007-074681

(51) Int. Cl. G02F 1/1345; H01L 21/00

(52) U.S. Cl. 349/151; 438/30; 257/E21.001

(57) ABSTRACT

A liquid crystal display device includes an array substrate, terminal electrodes formed on the array substrate, an anisotropic conductive film, a semiconductor device mounted via the anisotropic conductive film on the array substrate and a dummy pattern formed on the array substrate as facing the anisotropic conductive film. A manufacturing method of the liquid crystal display device includes forming the terminal electrodes and dummy pattern on the array substrate, temporarily pressure-bonding the anisotropic conductive film onto the terminal electrodes and dummy pattern and mounting the semiconductor device on the anisotropic conductive film through thermal compression bond.

### BACKGROUND OF THE INVENTION

1. Field of the Invention

The present invention relates to a COG liquid crystal display device having a semiconductor device (an IC chip) mounted directly on an array substrate and to a manufacturing method thereof.

2. Description of the Prior Art

Since the liquid crystal display device is a planar display device small in thickness, light in weight and low in power consumption, it has been used widely, such as in mobile devices including so-called PDAs and mobile telephones, in display portions of personal computers, etc.

The liquid crystal display device has a liquid crystal display panel of a structure in which a liquid crystal layer is sandwiched between a pair of display panel substrates, i.e. an array substrate and an opposing substrate. The liquid crystal layer is controlled through selective application of voltage to each of pixels between the array substrate and the opposing substrate to display images. Here, in a active matrix liquid crystal display panel, for example, a thin film transistor (TFT) using an amorphous silicon or polysilicon semiconductor is formed as a switching device on a array substrate, and a pixel electrode, scan lines and signal lines connected to the switching device are also formed thereon. On the other hand, formed on the opposing substrate are an opposing electrode formed of indium tin oxide (ITO) etc. and a color filter.

In the liquid crystal display device having the above configuration, a scan line drive circuit and a signal line drive circuit are built in the array substrate for the purpose of making the device thin and lightweight. Particularly, since the signal line drive circuit has to be operated at higher speed than the scan line drive circuit, it has been produced as an IC chip and mounted directly on the array substrate by means the so-called COG technique. The IC chip is mounted by connecting it via a bump onto a terminal electrode disposed on the outer edge of the array substrate and adapted to receive input signals from an external control circuit and to output image control signals to the scan lines or signal lines on the array substrate.

When mounting the IC chip, an anisotropic conductive film has been used widely for connection (refer, for example, to JP-A 2000-235349). The anisotripic conductive film is an adhesive film having conductive particles dispersed therein. The conductive particles are crashed between the electrodes through thermal compression bond, thereby attaining electrical continuity between the electrodes.

For example, JP-A 2000-235349 cited above discloses a method for manufacturing a liquid crystal device having a COG mount structure in which a liquid crystal driver IC is mounted directly on a liquid crystal device, which method comprises the steps of temporarily pressure-bonding the anisotropic conductive film onto the glass substrate, positioning the liquid crystal driver IC on the temporarily pressure-bonded anisotropic conductive film along an electrode pattern of the glass substrate and using a hot press to subject the liquid display device and liquid crystal driver IC to thermal compression bond.

In the meantime, when using the anisotropic conductive film to mount the semiconductor device (the liquid crystal driver IC) as disclosed in the aforementioned prior art, it is the general procedure comprising the steps of temporarily pressure-bonding the anisotropic conductive film and then thermally compression-bonding the semiconductor device. In this case, therefore, the state of the temporarily pressure-bonded anisotropic conductive film having been attached greatly affects the subsequent state of the semiconductor device to be thermally compression-bonded.

When temporarily pressure-bonding the anisotropic conductive film onto a glass substrate, for example, there is a case where part of the anisotropic conductive film fails to adhere to the glass plate because the glass plate has a flat and smooth surface. This case is frequently induced particularly in the portion of the glass substrate provided with no terminal electrode, resulting in posing problems, such as partial turnup of the anisotropic conductive film. When mounting the semiconductor device in that state, a mounting defect is possibly caused to lower the manufacturing yield.

The present invention has been proposed in view of the conventional state of affairs and the object thereof is to provide a liquid crystal display device capable of infallibly preventing turnup of an isotropic conductive film when being temporarily pressure bonded and being manufactured at high yields and further provide a manufacturing method thereof.

### SUMMARY OF THE INVENTION

To attain the above object, the present invention provides a liquid crystal display device comprising an array substrate, terminal electrodes formed on the array substrate, an anisotropic conductive film, a semiconductor device mounted via the anisotropic conductive film on the array substrate device and a dummy pattern formed on the array substrate as facing the anisotropic conductive film.

The present invention further provides a manufacturing method of a liquid crystal display device, comprising the steps of forming terminal electrodes and a dummy pattern on an array substrate, temporarily pressure-bonding an anisotropic conductive film onto the terminal electrodes and dummy pattern and mounting a semiconductor device on the anisotropic conductive film through thermal compression bond.

In the temporary pressure bond of the anisotropic conductive film, since the terminal electrodes are formed as projecting from the array substrate, the anisotropic conductive film is temporarily fixed onto the terminal electrodes. When the array substrate is formed of glass, however, there is a possibility of the anisotropic conductive film fails to adhere to the terminal electrodes due to the flat and smooth surface of the array substrate. In the present invention, therefore, a dummy pattern is formed on the array substrate besides the terminal electrodes. As a result, it is made possible to stable the state of the anisotropic conductive film temporarily pressure-bonded and prevent turnup of the anisotropic conductive film. Since the dummy pattern is formed as projecting from the array substrate similarly to the terminal electrodes, it serves to reinforce the state of the anisotropic conductive film temporarily fixed. Therefore, the anisotropic conductive film is temporarily pressure-bonded stably without inducing any turnup of the periphery thereof.

According to the present invention, since the dummy pattern is formed on the array substrate besides the terminal electrodes, it is made possible to provide a liquid crystal display device capable of infallibly preventing turnup of the anisotropic conductive film at the time of temporary pressure bonding thereof and excellent in reliability. Thus, the liquid crystal display device can be manufactured with high yields.

The above and other objects, characteristic features and advantages of the present invention will become apparent to those skilled in the art from the description to be given herein below with reference to the accompanying drawings.

### BRIEF DESCRIPTION OF THE DRAWINGS

FIG. 1 is a schematic plan view showing the configuration of a liquid crystal display device according to the present invention.

FIG. 2 is a schematic side view showing the configuration of the liquid crystal display device.

FIG. 3 is a schematic perspective view showing the principal part of one example of a dummy pattern formed on an array substrate.

FIG. 4 is a schematic plan view showing one example of a COG structure in which a driver LSI is mounted on an array substrate.

FIG. 5 is a schematic perspective view showing the principal part of another example of the dummy pattern formed on the array substrate.

FIG. 6 is a schematic plan view showing another example of the COG structure in which the driver LSI is mounted on the array substrate.

FIG. 7 shows the steps of forming the COG structure in which the driver LSI is mounted on the array substrate.

### DETAILED DESCRIPTION OF THE PREFERRED EMBODIMENTS

The liquid crystal display device and the manufacturing method thereof according to the present invention will be described hereinafter in detail with reference to the accompanying drawings.

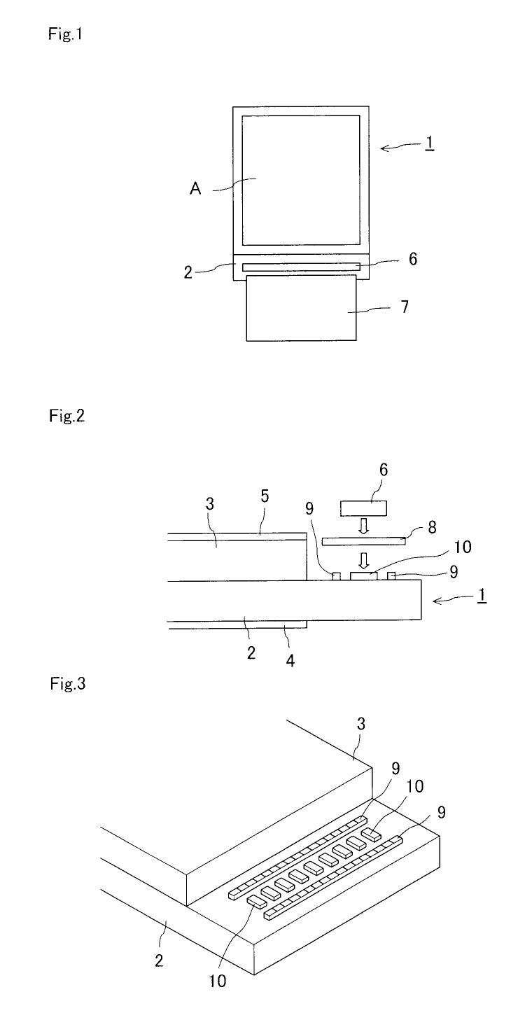

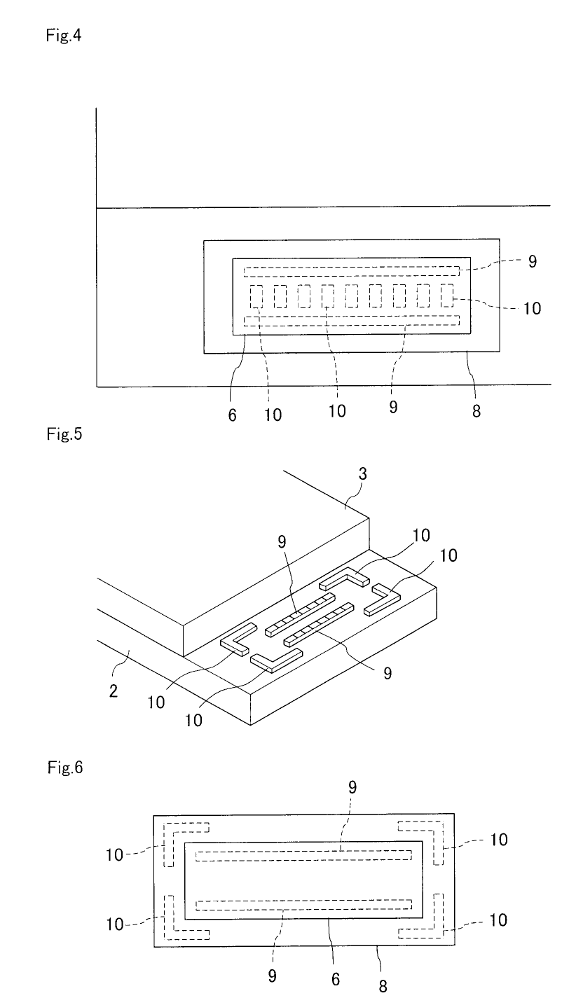

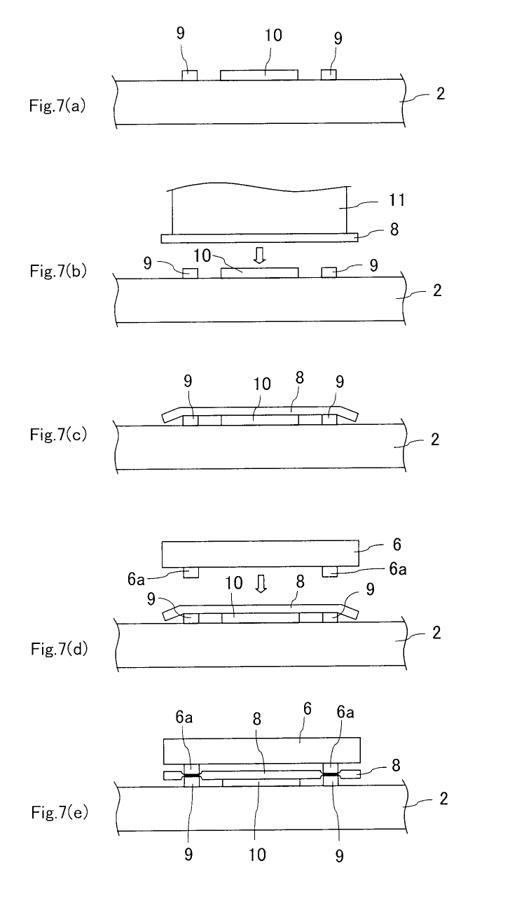

FIGS. 1 and 2 show one example of a liquid crystal display device 1 according to the present invention. In the liquid crystal display device 1, paired optically transparent insulated substrates constitute a liquid crystal cell and have a liquid crystal material sealed in therebetween to form a liquid crystal layer (not shown). Specifically, the liquid crystal layer is sealed in between an array substrate 2 and an opposing substrate 3. The array substrate 2 has as a support substrate an optically transparent insulated substrate formed of glass (a glass substrate) provided thereon with scan lines arranged in parallel and equidistantly, signal lines arranged substantially orthogonal to the scan lines, interlayer insulation films (transparent insulating films) intervening between the scan lines and signal lines to electrically insulate these and driver transistors (TFTs) disposed as switching devices in the vicinity of the intersections between the scan lines and the signal lines.

Also, in the array substrate 2, pixel electrodes electrically connected to the switching devices are formed in a matrix form via through holes. Though the pixel electrodes are generally formed as transparent electrodes, part thereof may be formed as reflecting electrodes to fabricate a semi-transmissive liquid crystal display device.

On the other hand, the opposing substrate 3 has an optically transparent insulating substrate made of glass, for example (a glass substrate) as a support substrate and has its surface on the side of a liquid crystal layer provided with a color filter layer corresponding to each of pixels. The entire surface of the color filter layer is coated with a transparent opposing electrode formed of a transparent conductive material, such as ITO. The color filter layer is a resin layer colored with pigment or dye and is composed of filter layers having colors of R, G and B, for example. Furthermore, the boundaries of the color filters between the pixels are provided with so-called black matrix layers for the purpose of enhancing color contrast.

In the liquid crystal display device 1 having the above configuration, the outer surfaces of the array substrate 2 and opposing substrate 3 are provided with polarization plates 4 and 5, respectively. Images are displayed on a display region A, with a backlight (a backside light source) disposed at the back as a light source. Furthermore, the array substrate 2 is disposed at the back and the opposing substrate is disposed at the front. In the liquid crystal display device 1 of this embodiment, therefore, disposed in order from the backside thereof are the backlight, polarization plate 4, array substrate 2, liquid crystal layers, opposing substrate 3 and polarization plate 5.

Also in the liquid crystal display device 1, the array substrate 2 is partially enlarged in comparison with the opposing substrate 3, and a COG structure in which a semiconductor device (a driver LSI) 6 is mounted on the enlarged portion of the array substrate 2 is formed. In addition, a flexible substrate 7 for supplying signals is connected to the outside of the driver LSI 6.

Here, the driver LSI 6 is mounted via the anisotropic conductive film 8 on the array substrate 2 that is provided thereon with terminal electrodes 9 corresponding in number to connection terminals 6a of the driver LSI 6. The driver LSI 6 is thermally pressure-bonded onto the array substrate 2 via the anisotropic conductive film 8 to electrically connect the connection terminals 6a and the terminal electrodes 9, thereby enabling transmission of signals between the driver LSI 6 and the array substrate 2.

When forming the COG structure in which the driver LSI 6 is mounted on the array substrate 2 using the anisotropic conductive film 8, the anisotropic conductive film 8 is temporarily pressure-bonded onto the array substrate 2 and then the driver LSI 6 is subjected to thermal compression bond. At this time, in the region between the terminal electrodes 9 of the array substrate 2 and in the vicinity of the region, it is necessary for the anisotropic conductive film 8 to be temporarily pressure-bonded onto the surface of the array substrate 2. However, since the surface of the array substrate is extremely flat and smooth, there is a possibility of the anisotropic conductive film 8 failing to be attached to the flat and smoother surface to possibly induce so-called floating. In addition, since the anisotropic conductive film 8 used has a larger area than the profile area of the driver LSI 6, insufficient attachment thereof to the array substrate 2 induces turnup around the insufficient attachment portion, resulting in a mounting failure.

In view of the above, as shown in FIGS. 3 and 4 in the present embodiment, a dummy pattern 10 is formed, besides the terminal electrodes 9, on the array substrate 2 so as to enable the temporary pressure bond of the anisotropic conductive film 8 with exactitude.

The dummy pattern 10 will be described in detail. As shown in FIG. 3 of the present embodiment, the dummy pattern 10 is formed by patterning a conductive layer formed of copper foil etc., similarly to the terminal electrodes 9, in the form of islands isolated so as not to be electrically connected to the terminal electrodes 9. FIG. 4 is a plan view showing the state of the COG structure in which the driver LSI 6 has been mounted via the anisotropic conductive film 8 on the terminal electrodes 9 and dummy pattern 10.

Similarly to the terminal electrodes 9, the dummy pattern 10 is formed as projecting from the array substrate 2. Therefore, when temporarily pressure-bonding the anisotropic conductive film 8, the pressure bonding force is exerted onto both the terminal electrodes 9 and the dummy pattern 10. As a result, the state of the anisotropic conductive film 8 temporarily pressure bonded is made stable, thus preventing floating or turnup of the anisotropic conductive film 8.

Similarly to the terminal electrodes 9, the dummy pattern 10 is formed as an electrode pattern. However, this is by no means limitative. It may be formed as an insulator pattern. If it is possible to form the dummy pattern 10 as a concavoconvex pattern on the array substrate 2, the material therefor and formation method thereof will be optional. In either case, however, it is preferable that the height of the dummy pattern 10 be equal to or lower than that of the terminal electrodes 9. When the height of the dummy pattern 10 is too high as exceeding the height of the terminal electrodes 9, the anisotropic conductive film 8 bulges to possibly pose a problem that mounting of the driver LSI 6 is hindered.

In addition, when the dummy pattern 10 is formed as the electrode pattern, it is possible to utilize the dummy pattern 10 as a ground pattern (an earth pattern). In this case, however, when the dummy pattern is formed as a very flat stereotypical pattern, it is noted that the dummy pattern possibly fails to satisfy its function.

Furthermore, the dummy pattern 10 in the present embodiment is formed between the terminal electrodes. However, this is by no means limitative. It can be formed at an optional position. In order to prevent turnup of the periphery of the anisotropic conductive film 8, it is effective, as shown in FIGS. 5 and 6, that the dummy patterns 10 be formed on the outer peripheries of the anisotropic conductive film 8.

Next, the method for manufacturing the liquid crystal display device will be described. FIG. 7 shows the order of the steps constituting a process for forming a COG structure in which the driver LSI 6 is mounted during the manufacture of the liquid crystal display device 1.

In forming a COG structure in which the driver LSI 6 is mounted on the array substrate 2, the terminal electrodes 9 and dummy pattern 10 are formed on the array substrate 2 as shown in FIG. 7(a). The terminal electrodes 9 and dummy pattern 10 are simultaneously formed into prescribed shapes through patterning of a conductive layer made of copper foil, for example utilizing the photolithographic technique. The formation of the dummy pattern 10 makes the surface of the array substrate 2 concavoconvex.

Next, as shown in FIG. 7(b), a jig 11 for temporary pressure bond is used to temporarily pressure-bond the anisotropic conductive film 8 onto the array substrate 2. The jig 11 may be formed of a material having some elasticity. As a result, uniform pressure can be applied along the lines of the surface of the array substrate 2.

At this time, since the terminal electrodes 9 and dummy pattern 10 are formed on the array substrate 2, the portions of the anisotropic conductive film 8 opposite to these are pressurized. As a result, the anisotropic conductive film 8 is temporarily fixed by means of both the terminal electrodes 9 and the dummy pattern 10 as shown in FIG. 7(c), thus attaining stable temporary pressure bond without inducing any floating or turnup.

After the temporary pressure bond of the anisotropic conductive film 8, as shown in FIG. 7(d), thermal compression bond is performed, with connection terminals 6a of the driver LSI 6 opposed to the terminal electrodes 9, thereby forming a COG structure in which the driver LSI 6 is mounted on the array substrate 2 as shown in FIG. 7(e). The conductive particles contained in the anisotropic conductive film 8 are broken by application of pressure between the connection terminals 6a and the terminal electrodes 9 to form electrical connection between the connection terminals 6a and the terminal electrodes 9. In addition, the adhesive constituting the anisotropic conductive film 8 allows the drive LSI 6 to be attached and fixed to the array substrate 2.

According to the manufacturing method described in the foregoing, it is made possible to temporarily pressure-bond the anisotropic conductive film 8 stably onto the array substrate 2, thereby avoiding a problem of poor connection due to turnup of the periphery of the anisotropic conductive film 8 and realizing a highly reliable connection state. Furthermore, the avoidance of the poor connection enables liquid crystal display devices to be manufactured at greatly enhanced yields.

What is claimed is:

1. A liquid crystal display device comprising:
an array substrate;
terminal electrodes formed on the array substrate;
an anisotropic conductive film;
a semiconductor device mounted via the anisotropic conductive film on the array substrate; and
a dummy pattern formed on the array substrate as facing the anisotropic conductive film.

2. A liquid crystal display device according to claim 1, wherein the dummy pattern comprises an island-like electrode pattern electrically isolated from the terminal electrodes.

3. A liquid crystal display device according to claim 1, wherein the dummy pattern has a height identical with or lower than a height of the terminal electrodes.

4. A liquid crystal display device according to claim 1, wherein the array substrate is formed of glass.

5. A manufacturing method of a liquid crystal display device, comprising the steps of:
forming terminal electrodes and a dummy pattern on an array substrate;
temporarily pressure-bonding an anisotropic conductive film onto the terminal electrodes and dummy pattern; and
mounting a semiconductor device on the anisotropic conductive film through thermal compression bond.

6. A manufacturing method of a liquid crystal display device according to claim 5, wherein the terminal electrodes and dummy pattern are formed on the array substrate simultaneously through patterning of a conductor layer formed on the array substrate.
